(19) United States
(12) Patent Application Publication
(10) Pub. No.: US 2026/0122834 A1
(43) Pub. Date: Apr. 30, 2026

(54) HEAT TRANSFER FEATURE WITH DROP-SHAPED BOSS

(71) Applicant: Eaton Intelligent Power Limited, Dublin (IE)

(72) Inventor: Kyle Alexander Hoyt, Grand Rapids, MI (US)

(21) Appl. No.: 19/045,637

(22) Filed: Feb. 5, 2025

Related U.S. Application Data
(60) Provisional application No. 63/552,052, filed on Feb. 9, 2024.

(51) Int. Cl. H05K 7/20

(52) U.S. Cl. CPC H05K 7/20154; H05K 7/20263; H05K 7/20272

(57) ABSTRACT

The present disclosure relates to an improved heat transfer feature and methods for removal of heat from one or more heat generating elements (for example, electrical components associated with systems such as motor controllers) mounted within a housing. The disclosed heat transfer feature includes a plurality of fins located within a flow path. The fins increase the surface area of the heat transfer area within the flow path, leading to more efficient cooling by a heat transfer fluid flowing through the flow path. The heat transfer area also includes one or more bosses. These undersides of these bosses provide recesses for fastening and mounting of the heat generating elements to the interior of the housing. In the disclosed examples, the bosses have a drop-shaped cross-section, which improves the flow of the heat transfer fluid around the bosses to result in more even cooling.

### CROSS-REFERENCE TO RELATED APPLICATION(S)

This application claims the benefit of U.S. Provisional Patent Application No. 63/552,052, filed Feb. 9, 2024, which is incorporated by reference herein in its entirety.

### BACKGROUND OF THE INVENTION

Electrical and mechanical components, for example, electrical components associated with motor controllers, and other types of equipment may generate heat. Overheating of such equipment/elements can negatively impact the performance, function, reliability, and/or structure of the heat-generating elements or other surrounding equipment. These heat-generating elements are often installed or mounted within cabinets or other enclosures or housings, making heat removal even more difficult. A heat transfer feature that can efficiently and evenly remove heat from one or more heat generating elements mounted within a housing is desired.

### SUMMARY OF THE INVENTION

The present disclosure relates to an improved heat transfer feature and methods for removal of heat from one or more heat generating elements (for example, electrical components) mounted within a housing. The disclosed heat transfer feature includes a plurality of fins located within a flow path of a heat transfer region/area. The fins increase the surface area of the heat transfer area within the flow path, leading to more efficient cooling by a heat transfer fluid flowing through the flow path. The heat transfer area also includes one or more bosses. These undersides of these bosses provide recesses for fastening and mounting of the heat generating elements to the interior of the housing. In the disclosed examples, the bosses have a drop-shaped cross-section, which improves the flow of the heat transfer fluid around the bosses to result in more even cooling.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 is a top perspective view of an example motor controller assembly, according to an example.

FIG. 2 is a top perspective view of the example motor controller assembly of FIG. 1, with a fan and lid removed.

FIG. 3 is a bottom perspective view of the example motor controller assembly of FIG. 1.

FIG. 4 is a bottom perspective view of the example motor controller assembly of FIG. 1, with electrical components and associated fasteners removed.

FIG. 5 is a top view of the example motor controller assembly of FIG. 1.

FIG. 6 is a first end view of the example motor controller assembly of FIG. 1.

FIG. 7 is a second end view of the example motor controller assembly of FIG. 1.

FIG. 8 is a partial cross-sectional view of a heat transfer area of the example motor controller assembly of FIG. 1.

FIG. 9 is a partial top view of a heat transfer area of the example motor controller assembly of FIG. 1.

FIG. 10A is a top schematic view of a first embodiment of a drop-shaped boss of a heat transfer area of the example motor controller assembly of FIG. 1.

FIG. 10B is a top schematic view of a second embodiment of a drop-shaped boss of a heat transfer area of the example motor controller assembly of FIG. 1.

FIG. 11A is an example flow schematic of an example circular boss.

FIG. 11B is an example flow schematic of an example shortened drop-shaped boss.

FIG. 11C is an example flow schematic of an example elongated drop-shaped boss.

FIG. 11D is an example flow schematic of an example drop-shaped boss of the heat transfer area of the example motor controller assembly of FIG. 1.

FIG. 12 is an example method of cooling one or more heat generating components, according to the example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. Examples may be practiced as methods, systems, or devices. The following detailed description is therefore not to be taken in a limiting sense, and the scope of the present disclosure is defined by the appended claims and their equivalents.

Other than in any included operating examples, or where otherwise indicated, all numbers expressing quantities, conditions, dimensions, or other measurements used herein should be understood as modified in all instances by the term “about.” The term “about” when used herein in connection with numerical values means±20% and with percentages means±2%.

Motor controllers and other types of electrical and mechanical equipment may generate heat. Overheating of these heat-generating elements/components can negatively impact the performance, function, reliability, and/or structure of the heat-generating components or other surrounding equipment, so maintaining the heat-generating components below a damaging temperature is beneficial. Such heat-generating elements/components are often installed or mounted within cabinets, boxes, or other housings, which hinders heat removal or dissipation. Addition of heat transfer features are added to these systems (for example to a housing) can add complexity to the system and can increase weight of the system. In some applications (for examples, aerospace applications), it is desired to minimize overall weight of the systems overall and thus of system features, while maintaining function and structural integrity.

The present disclosure relates to an improved heat transfer region/area and methods for removal of heat from one or more heat generating elements (for example, motor controllers) mounted within a housing/enclosure. In some examples, the heat generating elements are mounted to an interior of a wall of a housing/enclosure by the use of fasteners such as screws or bolts. The thickness of the wall of the housing may be determined so as to provide structural integrity, specific protections (for example, to meet industry standards, to be explosion-proof, etc.), to provide heat transfer, and/or to minimize weight. If the housing wall thickness is greater, structural integrity may be improved, but heat transfer capabilities may decrease and weight will increase. If the housing wall thickness is lesser, heat transfer capabilities may increase and weight will decrease, but the structural integrity of the housing may be lessened. In some examples, fasteners used to mount/connect/secure the heat generating elements to the interior of the housing may be longer than the thickness of the wall; the length of the fasteners may be determined based on a length necessary to adequately secure the elements. To accommodate for the length of the fasteners, a boss may protrude from an external side of the housing. The wall thickness of the boss may be determined based on minimizing weight, ensuring structural integrity of the protruding boss, and ensuring secure connection of the fastener.

Heat generated by the heat generating elements is transferred to the wall of the housing. To improve heat removal from the housing (and therefore, from the heat generating elements themselves), a heat transfer feature is positioned on the exterior of the housing, opposite the location on the interior of the housing where the heat generating elements are mounted. A heat transfer element flows through one or more flow paths defined by aspects of the heat transfer feature, to remove heat from the wall of the housing. In some examples, the heat transfer fluid is a gas, such as air, and such a gas may be driven along the flow path(s) via a fan or similar machine. In some examples, the heat transfer fluid is a liquid, such as water, and such a liquid may be driven along the flow path(s) via a pump or similar machine.

The footprint/size of the heat transfer feature on the housing exterior surface may be determined so as to ensure adequate heat removal (in some examples, to cover at least the footprint of the installed heat generating element(s)), to minimize weight, and to maintain structural integrity.

To increase surface area for heat removal, fins are located within the heat transfer feature. The fins define channels through which the heat transfer fluid may flow. While a greater number of fins and fins with geometries with sizes that maximize surface area may be advantageous for heat transfer, other factors (such as weight, fluid dynamics, manufacturability/machinability, and structural integrity) are also analyzed to determine the characteristics of the fins and the channels they define. Further, the width and length of channels defined between the fins may be selected so as to improve heat transfer and flow characteristics. For example, for a channel volume that is larger, for a given mass flow rate of heat transfer fluid the velocity of the fluid will be slower and the rate of heat removal may be slower in some examples. However, too small of a channel volume may restrict volume of heat transfer fluid flow, which can hinder heat removal. In some examples, a balance is achieved between a number of fins that maximizes surface area for heat transfer, and associated channels that do not restrict heat transfer fluid flow.

Because the heat transfer feature is positioned on the housing opposite the installed heat generating elements, one or more protruding bosses may be located within the heat transfer feature. These bosses may interrupt one or more of the fins, and may have a channel around their perimeter through which heat transfer fluid can flow. In the disclosed examples, the bosses have a drop-shaped cross-section/footprint, which improves the flow of the heat transfer fluid around the bosses to result in improved cooling. The drop-shaped bosses have a rounded end and a tail. The rounded end is oriented toward a flow inlet, and the tail end is oriented toward the flow outlet. The tail may be pointed or may include a second, smaller rounded portion. The size and shape of the boss may be determined based on fluid dynamics and heat transfer. For example, a round boss (or boss of another shape or size that is not preferred) may result in an area of low or stagnant flow downstream of the boss that results in hot spots where less heat transfer occurs. Such an area may be additionally problematic in an embodiment where the heat transfer fluid is a liquid, as areas of low pressure downstream of a non-preferred boss may cause cavitation, which can cause physical damage. A drop-shaped boss with a preferred shape and dimensions can cause the heat transfer fluid to flow in a manner that does not result in the area of low or stagnant flow downstream, resulting in more efficient and even heat transfer (and, in the case of a liquid heat transfer fluid, preventing the conditions that lead to cavitation).

To further improve cooling and flow dynamics of the heat transfer fluid, in some examples where a plurality of bosses are located within the heat transfer feature, the bosses may be aligned in one or more rows parallel to the fins.

The sizes and dimensions of the bosses, fins, and other features described herein may be manufactured by machining, molding, additive manufacturing, another suitable form of manufacturing, or a combination of manufacturing methods.

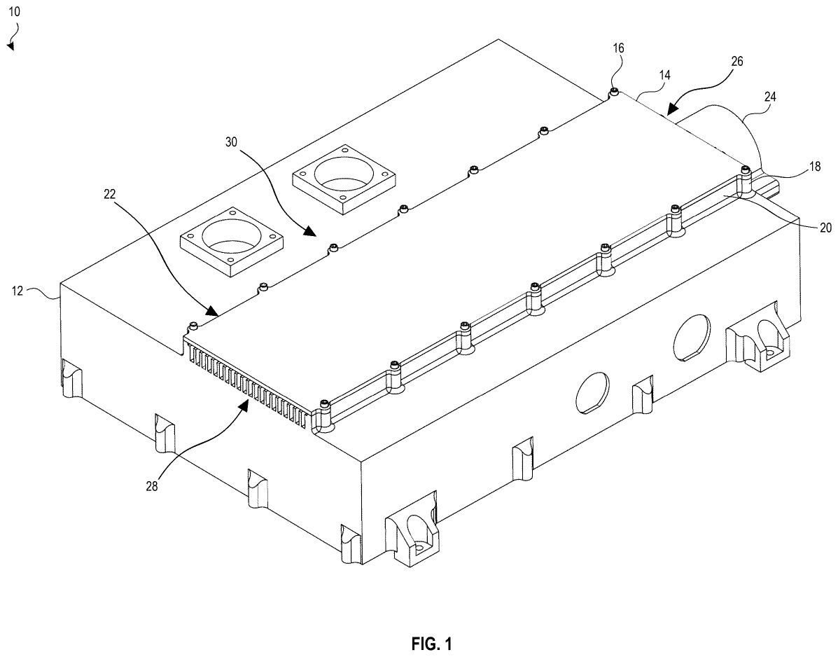

These and other examples will be explained in more detail below with respect to FIG. 1-FIG. 12.

In accordance with principles of this disclosure, FIG. 1 illustrates a top perspective view of an example motor controller assembly 10. While the particular examples shown correspond to a motor controller assembly with a motor controller and associated electrical components mounted within a housing, other examples of the disclosed features may apply to other heat-generating elements/components mounted within an enclosure. Motor controller assembly 10 includes a motor controller housing 12 that includes a heat transfer feature/heat transfer area/heat transfer region 22 on an exterior surface 30. Heat transfer area 22 is defined on two sides by a pair of parallel sidewalls 20 that extend from exterior surface 30. Heat transfer area 22 is further defined by a lid 14 that extends over heat transfer area 22 and is connected to the pair of sidewalls 20. Each of sidewalls 20 may include a plurality of connection features 18. In some examples, the connection features 18 may include recesses or receiving features for fasteners 16 for connection of the lid 14 to the sidewalls 20. Fasteners 16 may include screws, nails, bolts, tacks, rivets, or other features. In other examples, lid 14 may be connected to sidewalls 20 by gluing, welding, soldering, or other means of connection. In some examples, lid 14 may be removably connected to sidewalls 20. Heat transfer area 22 may be further defined by a flow inlet end 26 and an opposite flow outlet end 28.

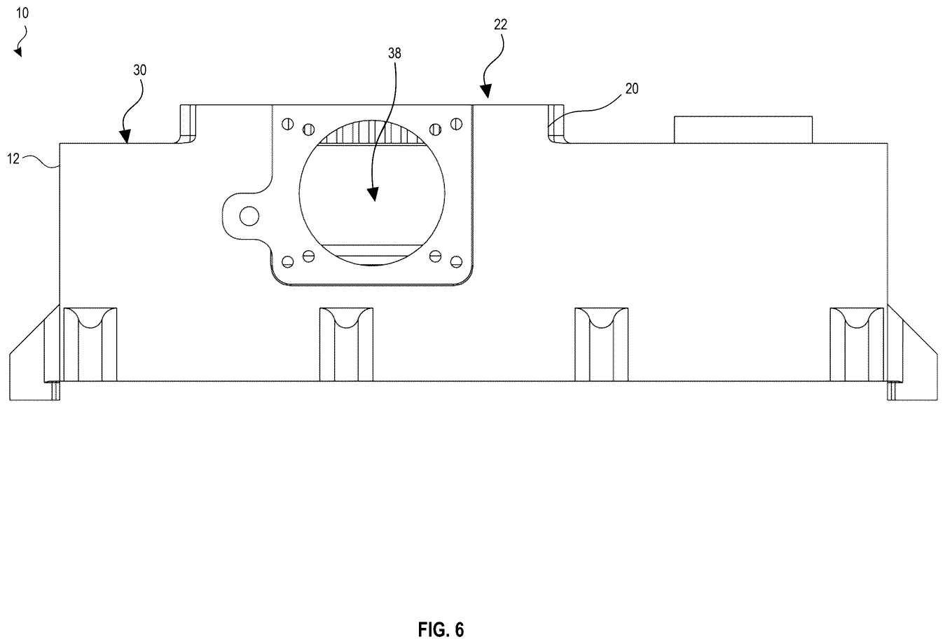

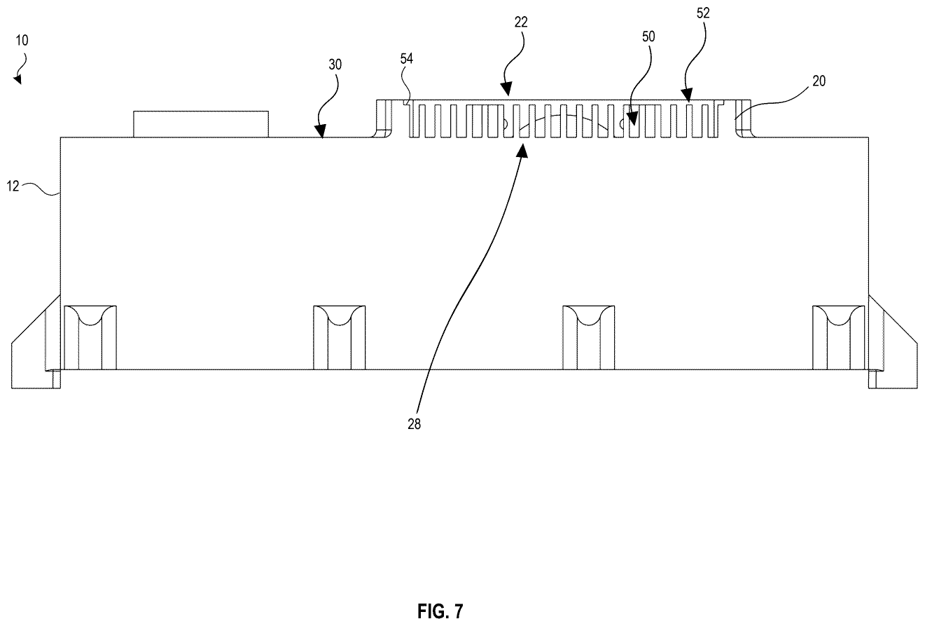

In some examples, a heat transfer fluid flows through the heat transfer area 22. In some examples, the heat transfer fluid is a gas, such as air or another suitable gas. In some examples, the heat transfer fluid is a liquid, such as water (for example, deionized water or another water type), a heat transfer oil, or another suitable liquid. In some examples, a machine such as fan 24 is connected to (e.g. removably or permanently mounted to) the housing 12 at the flow inlet end 26 to drive the heat transfer fluid through heat transfer area 22. In examples where the heat transfer fluid is a gas, the machine may be a fan 24 as shown in the particular example or a compressor. In examples where the heat transfer fluid is a pump, the machine may be a pump or other means of providing a liquid head. Refer also to: FIG. 6, which illustrates a first/inlet end view of the example motor controller assembly 10; and to FIG. 7, which illustrates a second/outlet end view of the example motor controller assembly 10.

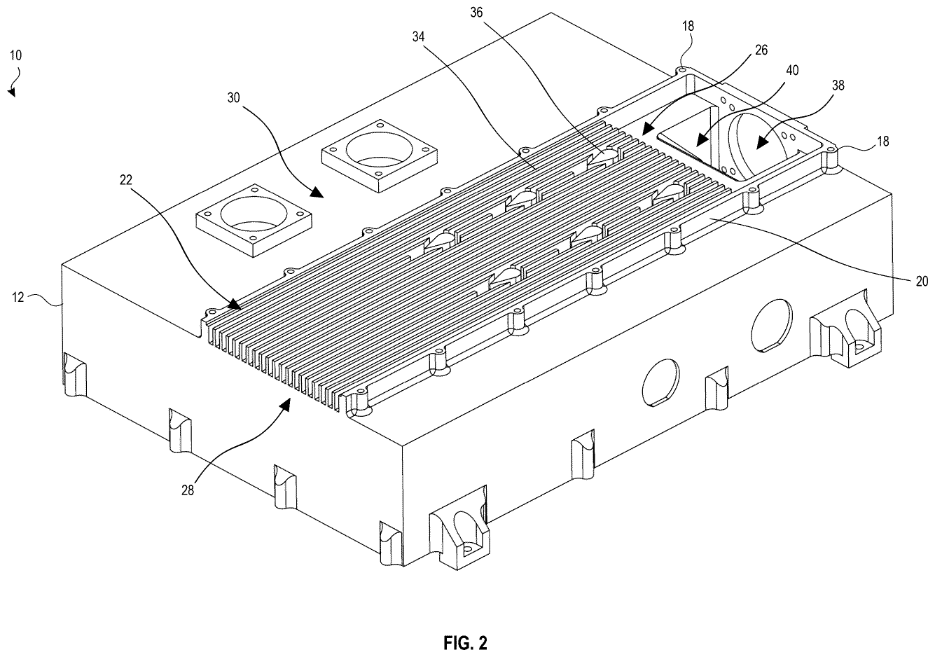

FIG. 2 illustrates a top perspective view of the example motor controller assembly 10, with a fan 24 and lid 14 removed. Housing 12 includes a flow inlet opening to allow the heat transfer fluid to flow into the flow inlet end 26 of the heat transfer area 22. In some examples, the heat transfer fluid first flows through a flow inlet volume 40 defined by the housing 12 and sidewalls 20. The lid 14 may also extend over the flow inlet volume 40. A plurality of heat transfer fins 34 extend from the exterior surface 30. The fins 34 are positioned parallel to the sidewalls 20. In some examples, the fins 34 are of uniform length, width, and/or height. In some examples, the fins 34 may have different lengths, widths, and/or heights. In some examples, the fins 34 are interrupted at one or more locations by one or more bosses 36. The bosses 36 extend from the surface 30 within the heat transfer area 22. In some examples, the bosses are drop (for example, shaped as a droplet or teardrop) shaped in a cross-section parallel to exterior surface 30. In other examples, the bosses 36 may have round, oval, elliptical, rectangular, square, semicircular, or other-shaped cross-section. While six bosses 36 are illustrated in the particular example shown, other numbers of bosses are possible in other examples.

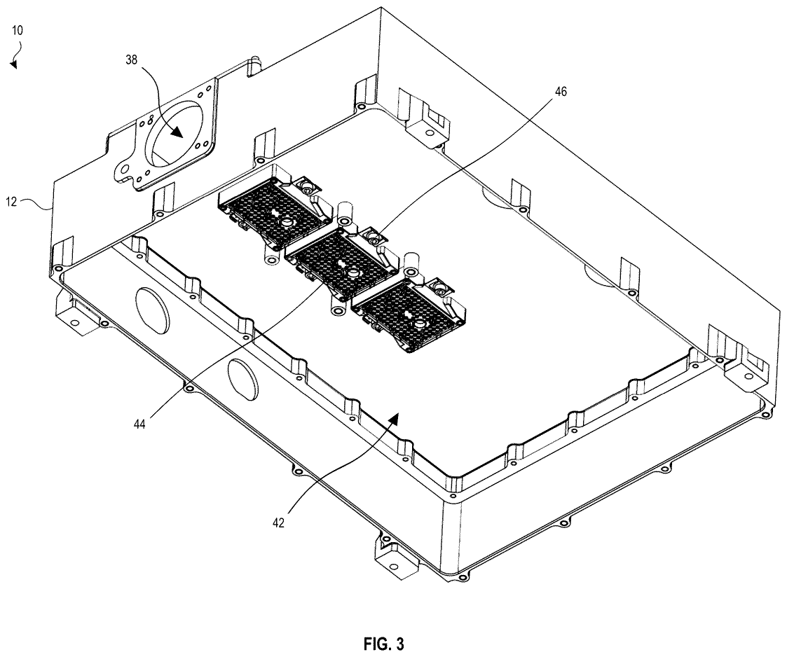

FIG. 3 illustrates a bottom perspective view of the example motor controller assembly 10. One or more electrical components 44 may be connected to/mounted to an interior surface 42 of housing 12. The electrical components 44 are mounted to the interior surface 42 opposite the heat transfer area 22, so that heat generated by the electrical components 44 is transferred through the housing 12 and to the features of the heat transfer area 22 and removed by the heat transfer fluid. The electrical components 44 may be mounted to the interior surface 42 by one or more fasteners 46. Fasteners 46 may include screws, nails, bolts, tacks, rivets, or other features. In some examples, fasteners 46 may be used in conjunction with a coiled locking insert or similar feature that fits inside of the recesses 48 (discussed below). In some examples, electrical components 44 may be removably mounted to the interior surface 42. While three electrical components 44, each having two fasteners 46, are illustrated in the particular example shown, other numbers of electrical components 44 having other numbers of fasteners 46 are possible in other examples.

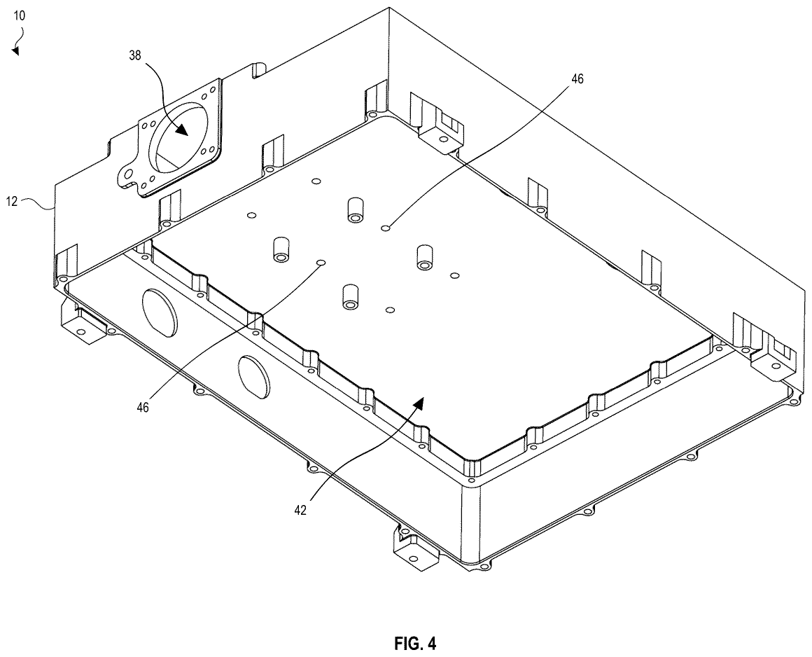

FIG. 4 illustrates a bottom perspective view of the example motor controller assembly 10 with electrical components 44 and associated fasteners 46 removed. The interior surface 42 includes one or more fastener recesses 48 that protrude into the underside of the bosses 36, which are located above the recesses 48. The recesses 48 are positioned and sized so as to receive the fasteners 46 to facilitate mounting of the electrical components 44 to the interior surface 42.

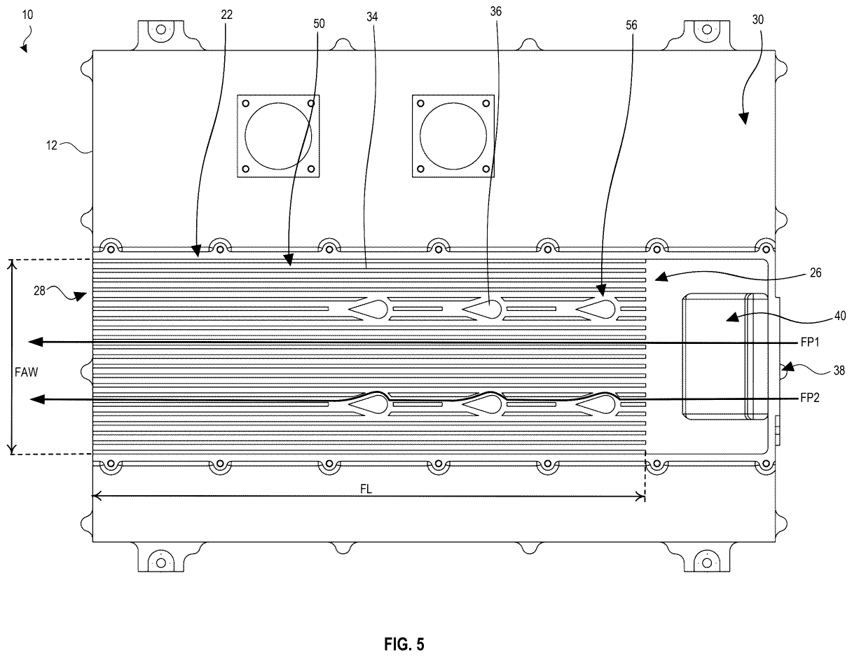

FIG. 5 illustrates a top view of the example motor controller assembly 10. The space between each of the fins 34 is a flow channel 50, through which the heat transfer fluid may flow. A around the perimeter of each boss 36 is a boss flow channel 56, through which the heat transfer fluid may flow. The boss flow channels 56 and the flow channels 50 define at least part of a flow path (which may be interpreted as a number of possible flow paths) for the heat transfer fluid to flow through the heat transfer area 22 from the flow inlet end 26 to the flow outlet end 28. In a particular example, heat transfer fluid may flow along a flow path FP1 through the flow inlet opening 38, through the flow inlet volume 40, and through one or more flow channels 50 (to exit the heat transfer area 22 at the flow outlet end 28). In another particular example, heat transfer fluid may flow along a flow path FP2 through the flow inlet opening 38, through the flow inlet volume 40, through one or more flow channels 50, and through all or part of one or more boss flow channels 56 (to exit the heat transfer area 22 at the flow outlet end 28). In passing through these flow paths, the heat transfer fluid absorbs heat energy from the surfaces of the flow channels 50, 56 (for example, the bosses 36, the exterior surface 30, the sidewalls 20, the fins 34, and/or the lid 14).

Referring now to FIG. 7, which illustrates a second/outlet end view of the example motor controller assembly 10, the heat transfer area may also include a flow gap 32, which is a volume above the fins 34 and below the lid 14. The height of the flow gap 32 may be determined by the location of a sidewall shoulder 54. In some examples, the height of the sidewall shoulder 54 is equal to the height of the fins 34. In some examples, the flow path(s) of the heat transfer fluid may include flowing through the flow gap 32 in addition to/in lieu of one or more of the flow channels 50, 56.

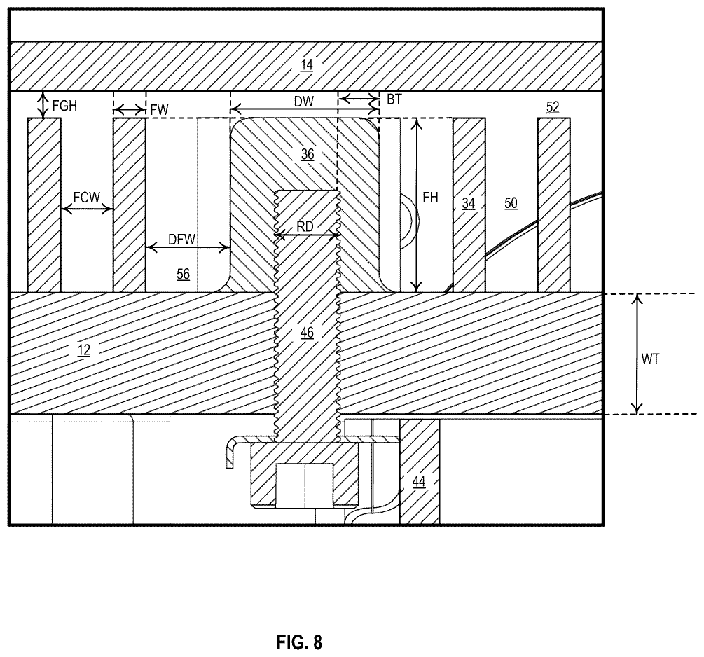

FIG. 8 illustrates a partial cross-sectional view of a heat transfer area 22 of the example motor controller assembly 10.

In some examples, a fin height FH (for example, extending the exterior surface 30) is determined so as to maximize heat transfer and/or minimize weight. The FH may be equal to the length of the sidewall 20 that sits below shoulder 54. In an example, all fins 34 have equal height. In some examples, the bosses 36 are equal in height to the FH. In such examples, the FH may be determined at least in part based on a length of fastener 46 that is required to securely mount electrical components 44. In other examples, the bosses 36 have a height that is greater than or less than the FH. In an example, the FH equals about 0.433 inches. In some examples, the FH equals about 0.4 inches. In some examples, the FH equals about 0.3 inches. In some examples, the FH equals about 0.5 inches. In some examples, the FH equals about 0.75 inches. In some examples, the FH equals about 1 inch. In some examples, the FH equals between about 0.4 inches and about 0.5 inches. In some examples, the FH equals between about 0.2 inches and about 1.0 inches. In some examples, the FH equals between about 0.3 inches and about 0.5 inches. In some examples, the FH equals between about 0.4 inches and about 0.45 inches. In some examples, the FH equals greater than about 0.433 inches. In some examples, the FH equals greater than about 0.4 inches. In some examples, the FH equals greater than about 0.2 inches. In some examples, the FH equals greater than about 0.3 inches. In some examples, the FH equals greater than about 1 inch. In some examples, the FH equals less than about 0.433 inches. In some examples, the FH equals less than about 0.45 inches. In some examples, the FH equals less than about 0.5 inches. In some examples, the FH equals less than about 0.3 inches. In some examples, the FH equals less than about 1 inch.

In some examples, a fin width FW (for example, the thickness of fins 34) is determined so as to maximize heat transfer, ensure adequate structural integrity of fins 34, and/or minimize weight. The FW may be equal for all fins 34 in some examples. In an example, the FW equals about 0.08 inches. In some examples, the FW equals about 0.06 inches. In some examples, the FW equals about 0.04 inches. In some examples, the FW equals about 0.10 inches. In some examples, the FW equals about 0.20 inch. In some examples, the FW equals between about 0.08 inches and about 0.10 inches. In some examples, the FW equals between about 0.01 inches and about 0.10 inches. In some examples, the FW equals between about 0.06 inches and about 0.10 inches. In some examples, the FW equals between about 0.07 inches and about 0.09 inches. In some examples, the FW equals greater than about 0.08 inches. In some examples, the FW equals greater than about 0.04 inches. In some examples, the FW equals greater than about 0.06 inches. In some examples, the FW equals greater than about 0.20 inch. In some examples, the FW equals less than about 0.08 inches. In some examples, the FW equals less than about 0.09 inches. In some examples, the FW equals less than about 0.10 inches. In some examples, the FW equals less than about 0.06 inches. In some examples, the FW equals less than about 0.20 inch.

In some examples, a fin length FL (refer to FIG. 5) (for example, extending from a flow inlet end 26 of the heat transfer area 22 to a flow outlet end 28) is determined so as to maximize heat transfer and/or minimize weight. The FL may be equal to the length of the fins 34 that are not interrupted by a boss 36. In an example, the FL equals about 12.16 inches. In some examples, the FL equals less than about 12 inches. In some examples, the FL equals less than about 10 inches. In some examples, the FL equals less than about 6 inches. In some examples, the FL equals less than about 4 inches. In some examples, the FL equals less than about 14 inches. In some examples, the FL equals less than about 16 inches. In some examples, the FL equals less than about 18 inches. In some examples, the FL equals less than about 24 inches. In some examples, the FL equals greater than about 12 inches. In some examples, the FL equals greater than about 10 inches. In some examples, the FL equals greater than about 6 inches. In some examples, the FL equals greater than about 4 inches. In some examples, the FL equals greater than about 14 inches. In some examples, the FL equals greater than about 16 inches. In some examples, the FL equals greater than about 18 inches. In some examples, the FL equals greater than about 24 inches. In some examples, the FL equals between about 11.5 inches and about 12.5 inches. In some examples, the FL equals between about 11 inches and about 13 inches. In some examples, the FL equals between about 10 inches and about 14 inches. In some examples, the FL equals between about 6 inches and about 18 inches. In some examples, the FL equals between about 6 inches and about 13 inches. In some examples, the FL equals between about 11 inches and about 18 inches.

In some examples, a flow area width FAW (refer to FIG. 5) (for example, the width between the parallel sidewalls 20) is determined so as to maximize heat transfer, to align opposite the mounted electrical components 44, and/or minimize weight. In an example, the FAW equals about 4.28 inches. In some examples, the FAW equals about 4 inches. In some examples, the FAW equals about 5 inches. In some examples, the FAW equals about 3.28 inches. In some examples, the FAW equals about 5.28 inches. In some examples, the FAW equals about 2 inches. In some examples, the FAW equals about 8 inches. In some examples, the FAW is greater than about 4 inches. In some examples, the FAW is greater than about 5 inches. In some examples, the FAW is greater than about 2 inches. In some examples, the FAW is greater than about 3 inches. In some examples, the FAW is less than about 4 inches. In some examples, the FAW is less than about 5 inches. In some examples, the FAW is less than about 12 inches. In some examples, the FAW is less than about 7 inches. In some examples, the FAW is between about 4.28 inches and about 5.28 inches. In some examples, the FAW is between about 3.28 inches and about 4.28 inches. In some examples, the FAW is between about 3.28 inches and about 5.28 inches. In some examples, the FAW is between about 4 inches and about 5 inches. In some examples, the FAW is between about 2 inches and about 7 inches.

In some examples, a flow channel width FCW (for example, the width of the flow channels 50 between fins 34) is determined so as to maximize heat transfer and optimize flow of the heat transfer fluid. The FCW may be equal for all flow channels 50, in some examples. In an example, the FCW equals about 0.13 inches. In some examples, the FCW equals about 0.1 inches. In some examples, the FCW equals about 0.2 inches. In some examples, the FCW equals about 0.05 inches. In some examples, the FCW equals about 0.5 inches. In some examples, the FCW is greater than about 0.05 inches. In some examples, the FCW is greater than about 0.1 inches. In some examples, the FCW is less than about 0.2 inches In some examples, the FCW is greater than about 0.5 inches. In some examples, the FCW equals between about 0.05 inches and about 0.5 inches. In some examples, the FCW equals between about 0.1 inches and about 0.2 inches. In some examples, the FCW equals between about 0.05 inches and about 1 inch.

In some examples, a drop/boss flow channel width DFW (for example, oriented around the perimeter of a boss 36) is determined so as to maximize heat transfer and to optimize flow of the heat transfer fluid. In some examples, the DFW is determined so as to fit a tool (e.g. a bit, drill, or other manufacturing tool) of a standard size. The DFW may be equal for all boss flow channels 56. In an example, the DFW may equal the FCW. In an example, the DFW may be greater than or less than the FCW. In an example, the DFW equals about 0.25 inches. In some examples, the DFW equals about 0.2 inches. In some examples, the DFW equals about 0.3 inches. In some examples, the DFW equals about 0.1 inches. In some examples, the DFW equals about 0.5 inches. In some examples, the DFW is greater than about 0.2 inches. In some examples, the DFW is greater than about 0.3 inches. In some examples, the DFW is greater than about 0.1 inches. In some examples, the DFW is greater than about 0.5 inches. In some examples, the DFW is greater than about 1 inch.

In some examples, a flow gap height FGH (for example, the distance between the shoulder 54 and an overall height of the sidewalls 20, where the sidewall height is greater than the FH and the shoulder 54 height is equal to the FH) is determined so as to maximize heat transfer, to optimize flow of the heat transfer fluid, and or for structural integrity of the sidewalls 20. In an example, the FGH equals about 0.067 inches. In some examples, the FGH equals about 0.06 inches. In some examples, the FGH equals about 0.07 inches. In some examples, the FGH equals about 0.1 inches. In some examples, the FGH equals about 0.05 inches. In some examples, the FGH is greater than about 0.06 inches. In some examples, the FGH is greater than about 0.07 inches. In some examples, the FGH is greater than about 0.01 inches. In some examples, the FGH is greater than about 0.05 inches. In some examples, the FGH is less than about 0.06 inches. In some examples, the FGH is less than about 0.07 inches. In some examples, the FGH is less than about 0.1 inches. In some examples, the FGH is less than about 0.05 inches. In some examples, the FGH is less than about 0.1 inches. In some examples, the FGH equals between about 0.05 inches and about 0.08 inches. In some examples, the FGH equals between about 0.01 inches and about 0.1 inches. In some examples, the FGH equals between about 0.06 inches and about 0.06 inches.

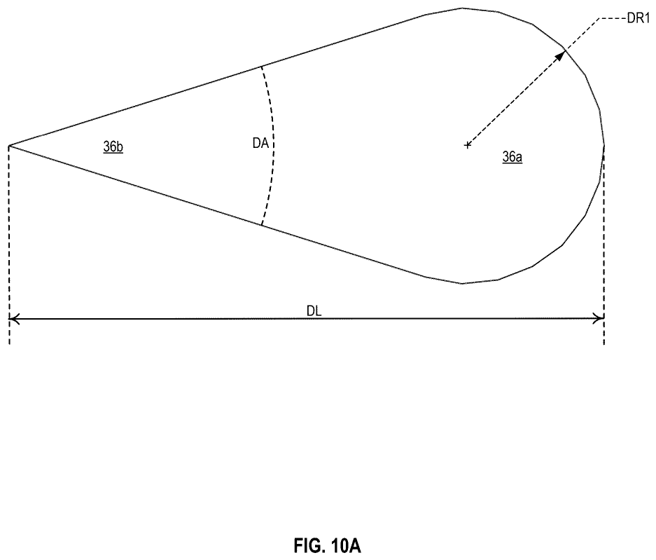

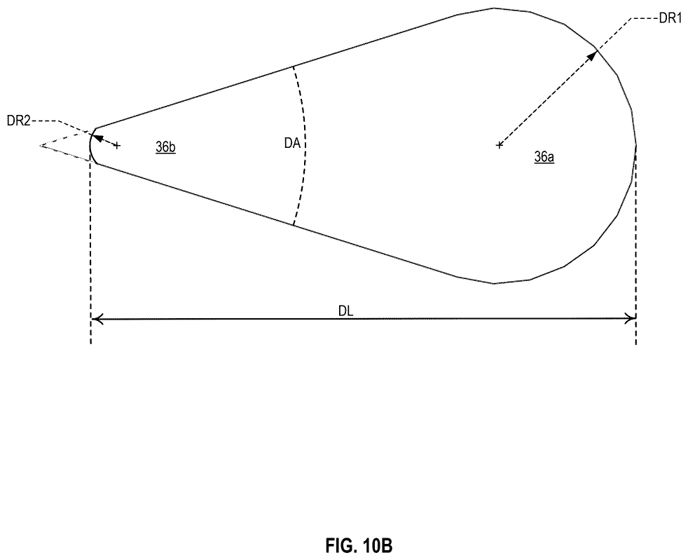

In some examples, a droplet/boss width DW (for example, the width of a boss 36 at its widest point, equal to double a droplet radius as described in FIGS. 10A and 10B) is determined at least in part on a recess diameter RD and a boss wall thickness BT.

In some examples, a recess diameter RD (for example, the diameter of the recess 48 that receives the motor controller fasteners 46) is determined so as to accommodate a fastener 46 that will securely mount electrical components 44. In an example, the RD equals about 0.178 inches. In some examples, the RD equals about 0.1 inches. In some examples, the RD equals about 0.2 inches. In some examples, the RD equals about 0.05 inches. In some examples, the RD equals about 0.3 inches. In some examples, the RD is greater than about 0.1 inches. In some examples, the RD greater than about 0.2 inches. In some examples, the RD greater than about 0.05 inches. In some examples, the RD greater than about 0.01 inches. In some examples, the RD is less than about 0.1 inches. In some examples, the RD is less than about 0.2 inches. In some examples, the RD is less than about 0.5 inches. In some examples, the RD is less than about 1 inch. In some examples, the RD is between about 0.01 inches and about 1 inch. In some examples, the RD is between about 0.1 inches and about 0.2 inches.

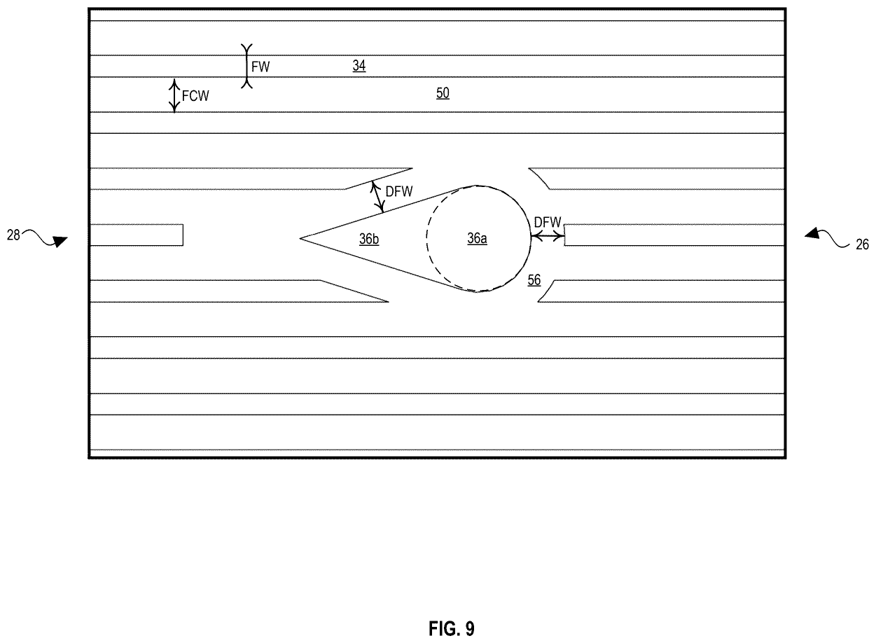

In some examples, a boss wall thickness BT (for example, a wall thickness of the material of the boss 36 around the recess 48) is determined so as to ensure structural integrity of the boss 36 and/or minimize weight. The thickness of the boss wall may vary from the rounded portion of the boss to the tail portion of the boss (see FIG. 9), and the BT as described in this paragraph refers to a wall thickness where the outer surface of the boss 36 is equal to the drop/boss radius DR1 as described below in FIGS. 10A and 10B. In an example, the BT equals about 0.11 inches. In some examples, the BD equals about 0.1 inches. In some examples, the BD equals about 0.2 inches. In some examples, the BD equals about 0.05 inches. In some examples, the BD equals about 0.3 inches. In some examples, the BD is greater than about 0.1 inches. In some examples, the BD greater than about 0.2 inches. In some examples, the BD greater than about 0.05 inches. In some examples, the BD greater than about 0.01 inches. In some examples, the BD is less than about 0.1 inches. In some examples, the BD is less than about 0.2 inches. In some examples, the BD is less than about 0.5 inches. In some examples, the BD is less than about 1 inch. In some examples, the BD is between about 0.01 inches and about 1 inch. In some examples, the BD is between about 0.1 inches and about 0.2 inches.

In some examples, a housing wall thickness WT (for example, the thickness of housing 12 between exterior surface 30 and interior surface 32) is determined so as to maximize heat transfer, minimize weight, and ensure structural integrity of housing 12. In an example, the WT equals about 0.3 inches. In some examples, the WT equals about 0.4 inches. In some examples, the WT equals about 0.2 inches. In some examples, the WT equals about 0.5 inches. In some examples, the WT equals about 0.1 inches. In some examples, the WT is greater than about 0.1 inches. In some examples, the WT is greater than about 0.2 inches. In some examples, the WT is greater than about 0.05 inches. In some examples, the WT is greater examples, the WT is less than about 0.3 inches. In some examples, the WT is less than about 0.4 inches. In some examples, the WT is less than about 0.5 inches. In some examples, the WT is less than about 1 inch. In some examples, the WT is between about 0.01 inches and about 1 inch. In some examples, the WT is between about 0.2 inches and about 0.4 inches.

FIG. 9 is a partial top view of a heat transfer area 22 of the example motor controller assembly 10. In some examples, a boss 36 may include a rounded portion 36a and a tail portion 36b. Rounded portion 36a may be circular, in some examples, and may be defined by a droplet/boss radius DR1 as defined in FIGS. 10A and 10B. In some examples, rounded portion 36a may be oriented toward the flow inlet end 26. In some examples, rounded portion may be oriented toward the flow inlet end 26. In some examples, tail portion 36b may be oriented toward the flow outlet end 28. In some examples, a tip of tail portion 36b is aligned with an end of a fin 34. In some examples, a tip of tail portion 36b is aligned with a channel 50.

FIG. 10A is a top schematic view of a first embodiment of a drop-shaped boss 36 of a heat transfer area 22 of the example motor controller assembly 10. In some examples, a rounded portion 36b of boss 36 is defined by a drop/boss radius DR1. In some examples, as discussed above, DR1 is determined at least in part based on the BT. In an example, the DR1 equals about 0.2 inches. In some examples, the DR1 equals about 0.1 inches. In some examples, the DR1 equals about 0.3 inches. In some examples, the DR1 equals about 0.05 inches. In some examples, the DR1 equals about 0.5 inches. In some examples, the DR1 is greater than about 0.1 inches. In some examples, the DR1 greater than about 0.2 inches. In some examples, the DR1 greater than about 0.05 inches. In some examples, the DR1 greater than about 0.01 inches. In some examples, the DR1 is less than about 0.3 inches. In some examples, the DR1 is less than about 0.2 inches. In some examples, the DR1 is less than about 0.5 inches. In some examples, the DR1 is less than about 1 inch. In some examples, the DR1 is between about 0.01 inches and about 1 inch. In some examples, the DR1 is between about 0.1 inches and about 0.3 inches.

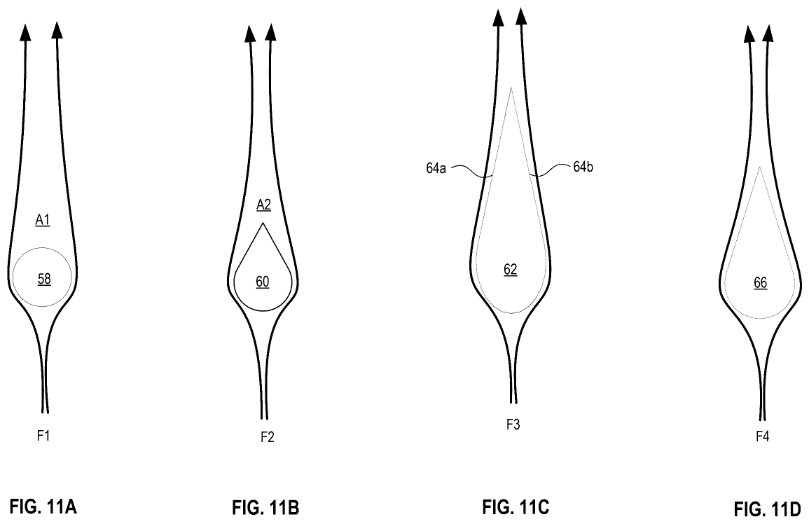

In some examples, the tail portion 36b is defined by a drop/boss angle DA. In some examples the DA is determined based at least in part on the DR1 and/or the length of the drop/boss DL, as described below and in FIGS. 11B-D. In an example, the DA equals about 35°. In some examples, the DA equals about 30°. In some examples, the DA equals about 40°. In some examples, the DA equals about 20°. In some examples, the DA equals about 50°. In some examples, the DA equals about 25°. In some examples, the DA equals about 45°. In some examples, the DA is less than about 35°. In some examples, the DA is less than about 30°. In some examples, the DA is less than about 40°. In some examples, the DA is less than about 50°. In some examples, the DA is less than about 45°. In some examples, the DA is greater than about 35°. In some examples, the DA is greater than about 30°. In some examples, the DA is greater than about 40°. In some examples, the DA is greater than about 10°. In some examples, the DA is less than about 25°. In some examples, the DA equals between about 35° and about 45°. In some examples, the DA equals between about 25° and about 35°. In some examples, the DA equals between about 25° and about 55°. In some examples, the DA equals between about 30° and about 40°. In some examples, the DA equals between about 10° and about 60°.

In some examples, a drop/boss length DL (for example, the length from a tip (pointed or rounded tip) of the tail portion 36b to the opposite surface of the rounded portion 36a) is determined so as to maximize heat transfer, to optimize flow of the heat transfer fluid (refer also to FIG. 11B-D), and/or minimize weight. In an example, the DL equals about 0.865 inches. In some examples, the DL equals about 0.8 inches. In some examples, the DL equals about 0.9 inches. In some examples, the DL equals about 0.75 inches. In some examples, the DL equals about 1 inch. In some examples, the DL is less than about 0.8 inches. In some examples, the DL is less than about 0.9 inches. In some examples, the DL is less than about 1.5 inches. In some examples, the DL is less than about 1 inch. In some examples, the DL is greater than about 0.8 inches. In some examples, the DL is greater than about 0.9 inches. In some examples, the DL is greater than about 0.75 inches. In some examples, the DL is greater than about 0.1 inches. In some examples, the DL is between about 0.1 inches and about 1.5 inches. In some examples, the DL is between about 0.8 inches and about 0.9 inches. In some examples, the DL is between about 0.4 inches and about 1.2 inches.

FIG. 10B is a top schematic view of a second embodiment of a drop-shaped boss 36 of a heat transfer area 22 of the example motor controller assembly 10. In some examples, the tip of the tail portion 36b is rounded. The rounded tip of the tail portion 36b may be defined by a drop/boss tail radius DR2, which may be is determined based on manufacturing requirements (for example, required path of a manufacturing bit or other tool). In an example, the DR2 equals about 0.02 inches. In some examples, the DR2 equals about 0.01 inches. In some examples, the DR2 equals about 0.03 inches. In some examples, the DR2 equals about 0.005 inches. In some examples, the DR2 equals about 0.05 inches. In some examples, the DR2 is greater than about 0.01 inches. In some examples, the DR2 is greater than about 0.02 inches. In some examples, the DR2 is greater than about 0.005 inches. In some examples, the DR2 is greater than about 0.001 inches. In some examples, the DR2 is less than about 0.03 inches. In some examples, the DR2 is less than about 0.02 inches. In some examples, the DR2 is less than about 0.05 inches. In some examples, the DR2 is less than about 0.1 inches. In some examples, the DR2 is between about 0.001 inches and about 0.1 inches. In some examples, the DR2 is between about 0.01 inches and about 0.03 inches.

In such an example where the tip of the tail portion 36b is rounded, the DL may be less, for a boss 36 of equal DR1, than it would have preferably been if the boss 36 had a pointed tail portion 36b tip.

FIG. 11A is an example flow schematic of an example circular boss 58. In such an example, when a flow F1 of heat transfer fluid encounters the circular boss 58, it is deflected around the circular boss 58. As the heat transfer fluid passes the circular boss 58, an area A1 of low or stagnant flow will form immediately downstream of the circular boss 58, and a portion of the heat transfer fluid may even flow back (upstream) toward the downstream side of the circular boss 58. In area A1, heat transfer is poor/inefficient due to the low, stagnant, and/or recirculating flow of the heat transfer fluid.

FIG. 11B is an example flow schematic of an example shortened drop-shaped boss 60. In such an example, when a flow F2 of heat transfer fluid encounters the shortened drop-shaped boss 60, it is deflected around the shortened drop-shaped boss 60. As the heat transfer fluid passes the shortened drop-shaped boss 60, an area A2 of low or stagnant flow may form immediately downstream of the shortened drop-shaped boss 60, and a portion of the heat transfer fluid may even flow back (upstream) toward the downstream side of the shortened drop-shaped boss 60. In area A2, heat transfer is poor/inefficient due to the low, stagnant, and/or recirculating flow of the heat transfer fluid. However, the area A2 created by the shortened drop-shaped boss 60 may be smaller than the area A1 created by the circular boss 58 and may result in somewhat improved heat transfer over the circular boss 58.

FIG. 11C is an example flow schematic of an example elongated drop-shaped boss 62. In such an example, when a flow F3 of heat transfer fluid encounters the elongated drop-shaped boss 62, it is deflected around the elongated drop-shaped boss 62. As the heat transfer fluid passes the elongated drop-shaped boss 62, no (or a minimal) area of low or stagnant flow may form immediately downstream of the elongated drop-shaped boss 62. When an elongated drop-shaped boss 62 is utilized, heat transfer is improved (over a circular boss 58 or a shortened drop-shaped boss 60, for example) due to the improved flow of the heat transfer fluid. However, if the length of the elongated drop-shaped boss 62 is too great, the flow of heat transfer fluid along the extra length of elongated boss sides 64a and 64b may result in added friction and less than optimal fluid flow properties. Further, an elongated drop-shaped boss 62 may include more material, and therefore more weight, than a shorter drop-shaped boss.

FIG. 11D is an example flow schematic of an example drop-shaped boss 66 (for example, boss 36 of the heat transfer area 22 of the example motor controller assembly 10). In such a preferred example, when a flow F4 of heat transfer fluid encounters the drop-shaped boss 66, it is deflected around the drop-shaped boss 66. As the heat transfer fluid passes the drop-shaped boss 66, no (or a minimal) area of low or stagnant flow may form immediately downstream of the drop-shaped boss 66. When a drop-shaped boss 66 is utilized, heat transfer is improved (over a circular boss 58 or a shortened drop-shaped boss 60, for example) due to the improved flow of the heat transfer fluid. Additionally, by preventing the sides and length of the drop-shaped boss 66 from becoming too long, the fluid flow properties of the heat transfer fluid along the sides and the weight of the drop-shaped boss 66 may be optimized.

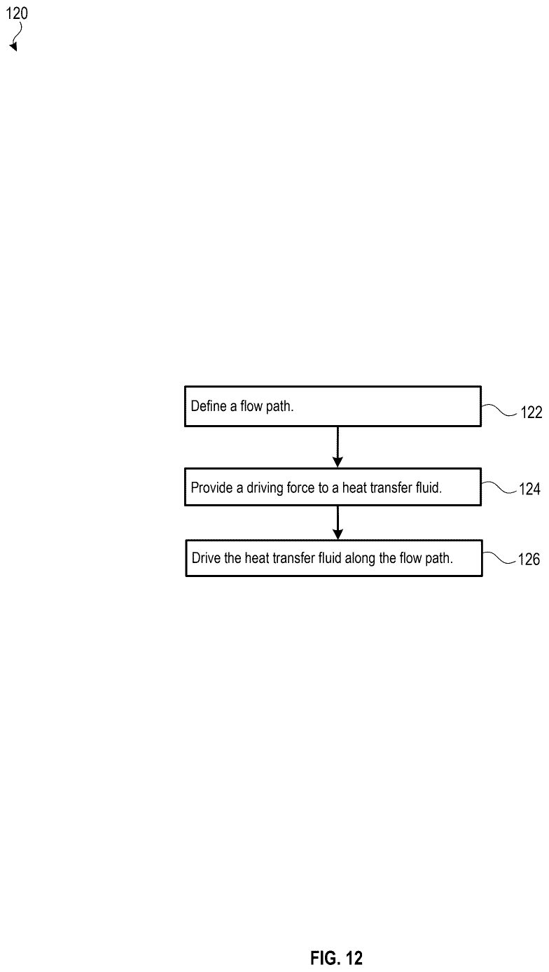

FIG. 12 is an example method 120 of cooling one or more heat generating components (for example, for cooling one or more electrical components 44). At operation 122, a flow path is defined through a heat transfer region on a first surface of a housing. The heat generating component (in some examples, the heat generating component is one of a plurality of heat generating components) is mounted to a second surface of the housing opposite the first surface. The heat transfer region is bounded by the first surface, a pair of sidewalls extending from the first surface, and a lid extending over the flow path and connected to the pair of sidewalls.

The flow path may include a first plurality of channels defined between each of a plurality of parallel fins disposed between the pair of sidewalls and a second plurality of channels defined around perimeters of one or more bosses. Each boss may interrupt at least one of the parallel fins. Each boss comprises a rounded portion and a tail portion. The rounded portion is oriented toward a flow path inlet of the heat transfer region, and the tail portion is oriented toward a flow path outlet of the heat transfer region.

At operation 124, a driving force is provided to a heat transfer fluid at the flow path inlet. In some examples, the driving force may be provided to the heat transfer fluid by a fan, for example, where the heat transfer fluid is a gas. In some examples, the driving force may be provided to the heat transfer fluid by a pump, for example, where the heat transfer fluid is a liquid.

At operation 126, the heat transfer fluid is driven along the flow path toward the flow path outlet. In some examples, heat/thermal energy is removed from the heat generating component by the heat transfer fluid.

For the purposes of this application, terms such as “upper,” “lower,” “upward,” and “downward” are intended to be descriptive with reference to and in relation to the orientation shown in the Figures for clarity, but the examples as practiced and included in the scope of the claims may include examples where the systems and devices are in a different orientation.

While particular uses of the technology have been illustrated and discussed above, the disclosed technology can be used with a variety of environments in accordance with many examples of the technology. The above discussion is not meant to suggest that the disclosed technology is only suitable for implementation within the environments shown and described above. As should be appreciated, the various aspects described with respect to the figures herein are not intended to limit the technology to the particular aspects described. Accordingly, additional configurations can be used to practice the technology herein and/or some aspects described can be excluded without departing from the methods and systems disclosed herein.

This disclosure described some aspects of the present technology with reference to the accompanying drawings, in which only some of the possible aspects were shown. Other aspects can, however, be embodied in many different forms and should not be construed as limited to the aspects set forth herein. Rather, these aspects were provided so that this disclosure was thorough and complete and fully conveyed the scope of the possible aspects to those skilled in the art.

Similarly, where operations of a process are disclosed, those operations are described for purposes of illustrating the present technology and are not intended to limit the disclosure to a particular sequence of operations. For example, the operations can be performed in differing order, two or more operations can be performed concurrently, additional operations can be performed, and disclosed operations can be excluded without departing from the present disclosure. Further, each operation can be accomplished via one or more sub-operations. The disclosed processes can be repeated.

Although specific aspects were described herein, the scope of the technology is not limited to those specific aspects. One skilled in the art will recognize other aspects or improvements that are within the scope of the present technology. Therefore, the specific structure, acts, or operations are disclosed only as illustrative aspects. The scope of the technology is defined by the following claims and any equivalents therein. Examples of the disclosure may be described according to the following aspects.

Aspect 1. An enclosure arrangement, comprising: a housing; a heat generating component mounted at a first surface of the housing; and a heat transfer region disposed at a second surface of the housing opposite the heat generating component, the heat transfer region comprising: a plurality of fins disposed at the heat transfer region, the fins extending parallel to each other to define channels therebetween, the channels extending between the inlet and outlet of the heat transfer region, a first of the fins being interrupted at a boss region disposed at an intermediate location along the first fin, the boss region separating a first of the channels into a first section and a second section; and a boss disposed at the boss region, the boss comprising a rounded portion and a tail portion, the rounded portion facing toward the first section of the first channel, the tail portion facing toward the second section of the first channel, the boss having a perimeter defining a flow path between the first section of the first channel and the second section of the first channel.

Aspect 2. The enclosure arrangement of aspect 1, wherein the boss region also separates a second of the channels into respective first and second sections, the first fin separating the first and second channels, the rounded portion of the boss facing toward the first section of the second channel, and the tail portion of the boss facing toward the second section of the second channel.

Aspect 3. The enclosure arrangement of any one of aspects 1-2, wherein the boss region is one of a plurality of boss regions, each boss region interrupting at least one respective fin; and wherein the boss is one of a plurality of bosses, each boss being located at a respective boss region.

Aspect 4. The enclosure arrangement of any one of aspects 1-3, wherein the heat generating component is one of a plurality of heat generating components.

Aspect 5. The enclosure arrangement of any one of aspects 1-4, wherein the heat generating component comprises an electrical component.

Aspect 6. The enclosure arrangement of any one of aspects 1-5, wherein: the heat generating component is removably mounted to the first surface, and the boss comprises a recess for receiving a fastener of the heat generating component.

Aspect 7. The enclosure arrangement of any one of aspects 1-6, further comprising a lid extending over the heat transfer region.

Aspect 8. The enclosure arrangement of any one of aspects 1-7, further comprising a machine connected to the housing configured to drive a heat transfer fluid along the flow path from the inlet to the outlet of the heat transfer region.

Aspect 9. The enclosure arrangement of aspect 8, wherein the heat transfer fluid comprises a gas.

Aspect 10. The enclosure arrangement of aspect 8, wherein the heat transfer fluid comprises a liquid.

Aspect 11. The enclosure arrangement of any one of aspects 1-10, wherein: the rounded portion is defined by a first radius, and the tail portion comprises a rounded tip defined by a second radius.

Aspect 12. A heat transfer apparatus, comprising: a heat transfer region disposed at a first surface of a housing, wherein the heat generating component mounted to a second surface of the housing opposite the heat transfer region; a plurality of fins disposed at the heat transfer region, the fins extending parallel to each other to define channels therebetween, the channels extending between the inlet and outlet of the heat transfer region, a first of the fins being interrupted at a boss region disposed at an intermediate location along the first fin, the boss region separating a first of the channels into a first section and a second section; and a boss disposed at the boss region, the boss comprising a rounded portion and a tail portion, the rounded portion facing toward the first section of the first channel, the tail portion facing toward the second section of the first channel, the boss comprising a recess for receiving a fastener of the heat generating component, the boss having a perimeter defining a flow path between the first section of the first channel and the second section of the first channel.

Aspect 13. The heat transfer apparatus of aspect 12, further comprising a machine connected to the housing configured to drive a heat transfer fluid along the flow path from the inlet to the outlet of the heat transfer region.

Aspect 14. The heat transfer apparatus of aspect 13, wherein the heat transfer fluid comprises a gas.

Aspect 15. The heat transfer apparatus of aspect 13, wherein the heat transfer fluid comprises a liquid.

Aspect 16. A method of cooling heat generating component, the method comprising: defining a flow path through a heat transfer region on a first surface of a housing, wherein: the heat generating component is mounted to a second surface of the housing opposite the first surface, the heat transfer region is bounded by the first surface, a pair of sidewalls extending from the first surface, and a lid extending over the flow path and connected to the pair of sidewalls, and the flow path comprises: a first plurality of channels defined between each of a plurality of parallel fins disposed between the pair of sidewalls; and a second plurality of channels defined around perimeters of one or more bosses, wherein each boss interrupts at least one of the parallel fins, and wherein: each boss comprises a rounded portion and a tail portion, the rounded portion is oriented toward a flow path inlet of the heat transfer region, and the tail portion is oriented toward a flow path outlet of the heat transfer region; providing a driving force to a heat transfer fluid at the flow path inlet; and driving the heat transfer fluid along the flow path toward the flow path outlet.

Aspect 17. The method of aspect 16, further comprising providing a driving force to a heat transfer fluid via a fan.

Aspect 18. The method of aspect 16, further comprising providing a driving force to a heat transfer fluid via a pump.

Aspect 19. The method of any one of aspects 16-18, wherein the heat generating component is one of a plurality of heat generating components.

Aspect 20. The method of any one of aspects 16-19, further comprising: mounting the heat generating component to the second surface, comprising inserting a fastener into a recess in each boss.

What is claimed is:

1. An enclosure arrangement, comprising:
a housing;
a heat generating component mounted at a first surface of the housing; and
a heat transfer region disposed at a second surface of the housing opposite the heat generating component, the heat transfer region comprising:
a plurality of fins disposed at the heat transfer region, the fins extending parallel to each other to define channels therebetween, the channels extending between the inlet and outlet of the heat transfer region, a first of the fins being interrupted at a boss region disposed at an intermediate location along the first fin, the boss region separating a first of the channels into a first section and a second section; and
a boss disposed at the boss region, the boss comprising a rounded portion and a tail portion, the rounded portion facing toward the first section of the first channel, the tail portion facing toward the second section of the first channel, the boss having a perimeter defining a flow path between the first section of the first channel and the second section of the first channel.

2. The enclosure arrangement of claim 1, wherein the boss region also separates a second of the channels into respective first and second sections, the first fin separating the first and second channels, the rounded portion of the boss facing toward the first section of the second channel, and the tail portion of the boss facing toward the second section of the second channel.

3. The enclosure arrangement of claim 1, wherein the boss region is one of a plurality of boss regions, each boss region interrupting at least one respective fin; and wherein the boss is one of a plurality of bosses, each boss being located at a respective boss region.

4. The enclosure arrangement of claim 1, wherein the heat generating component is one of a plurality of heat generating components.

5. The enclosure arrangement of claim 1, wherein the heat generating component comprises an electrical component.

6. The enclosure arrangement of claim 1, wherein:
the heat generating component is removably mounted to the first surface, and
the boss comprises a recess for receiving a fastener of the heat generating component.

7. The enclosure arrangement of claim 1, further comprising a lid extending over the heat transfer region.

8. The enclosure arrangement of claim 1, further comprising a machine connected to the housing configured to drive a heat transfer fluid along the flow path from the inlet to the outlet of the heat transfer region.

9. The enclosure arrangement of claim 8, wherein the heat transfer fluid comprises a gas.

10. The enclosure arrangement of claim 8, wherein the heat transfer fluid comprises a liquid.

11. The enclosure arrangement of claim 1, wherein:
the rounded portion is defined by a first radius, and
the tail portion comprises a rounded tip defined by a second radius.

12. A heat transfer apparatus, comprising:
a heat transfer region disposed at a first surface of a housing, wherein the heat generating component mounted to a second surface of the housing opposite the heat transfer region;
a plurality of fins disposed at the heat transfer region, the fins extending parallel to each other to define channels therebetween, the channels extending between the inlet and outlet of the heat transfer region, a first of the fins being interrupted at a boss region disposed at an intermediate location along the first fin, the boss region separating a first of the channels into a first section and a second section; and
a boss disposed at the boss region, the boss comprising a rounded portion and a tail portion, the rounded portion facing toward the first section of the first channel, the tail portion facing toward the second section of the first channel, the boss comprising a recess for receiving a fastener of the heat generating component, the boss having a perimeter defining a flow path between the first section of the first channel and the second section of the first channel.

13. The heat transfer apparatus of claim 12, further comprising a machine connected to the housing configured to drive a heat transfer fluid along the flow path from the inlet to the outlet of the heat transfer region.

14. The heat transfer apparatus of claim 13, wherein the heat transfer fluid comprises a gas.

15. The heat transfer apparatus of claim 13, wherein the heat transfer fluid comprises a liquid.

16. A method of cooling heat generating component, the method comprising:
defining a flow path through a heat transfer region on a first surface of a housing, wherein:
the heat generating component is mounted to a second surface of the housing opposite the first surface,
the heat transfer region is bounded by the first surface, a pair of sidewalls extending from the first surface, and a lid extending over the flow path and connected to the pair of sidewalls, and
the flow path comprises:
a first plurality of channels defined between each of a plurality of parallel fins disposed between the pair of sidewalls; and
a second plurality of channels defined around perimeters of one or more bosses, wherein each boss interrupts at least one of the parallel fins, and wherein:
each boss comprises a rounded portion and a tail portion,
the rounded portion is oriented toward a flow path inlet of the heat transfer region, and
the tail portion is oriented toward a flow path outlet of the heat transfer region;
providing a driving force to a heat transfer fluid at the flow path inlet; and
driving the heat transfer fluid along the flow path toward the flow path outlet.

17. The method of claim 16, further comprising providing a driving force to a heat transfer fluid via a fan.

18. The method of claim 16, further comprising providing a driving force to a heat transfer fluid via a pump.

19. The method of claim 16, wherein:
the heat generating component is one of a plurality of heat generating components.

20. The method of claim 16, further comprising:
mounting the heat generating component to the second surface, comprising inserting a fastener into a recess in each boss.
